(19) United States
(12) Patent Application Publication
(10) Pub. No.: US 2024/0332117 A1
(43) Pub. Date: Oct. 3, 2024

(54) POWER MODULE UTILIZING INJECTABLE CONDUCTIVE COMPONENT FOR DIRECT COOLING

(71) Applicant: SEMICONDUCTOR COMPONENTS INDUSTRIES, LLC, Scottsdale, AZ (US)

(72) Inventors: Changsun Yun, Seoul (KR); Oseob JEON, Seoul (KR)

(73) Assignee: SEMICONDUCTOR COMPONENTS INDUSTRIES, LLC, Scottsdale, AZ (US)

(21) Appl. No.: 18/295,217

(22) Filed: Apr. 3, 2023

(51) Int. Cl. H01L 23/367; H01L 23/04; H01L 23/42

(52) U.S. Cl. CPC H01L 23/3675; H01L 23/041; H01L 23/42; H01L 23/315

(57) ABSTRACT

An injectable conductive component can be used to couple a high-power semiconductor chip assembly to a heat sink, in automotive and industrial applications. The injectable conductive component provides a low-resistance interface material and also acts as a bonding agent. A cavity bounded by the chip assembly and the heat sink can form a container for the injectable conductive component, which remains in a liquid phase during operation of the chip assembly. The container can be formed as a cavity by either removing a portion of the heat sink, or by introducing a spacer between the chip assembly and the heat sink, using a sealing material. The injectable conductive component can be introduced into the cavity by injection through a hole formed in a back side of the heat sink.

### TECHNICAL FIELD

This description relates to assembling and packaging semiconductor device modules, semiconductor device assemblies, and semiconductor devices. More specifically, this description relates to efficient heat transfer from high power semiconductor device assemblies to a heat sink.

### BACKGROUND

Semiconductor device assemblies, e.g., chip assemblies, that include power semiconductor devices can be implemented using multiple semiconductor dies, substrates (e.g., direct-bonded metal substrates, die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to an apparatus, including: an electronic power assembly; a heat sink having a base plate and a plurality of fins; a perimeter wall extending from a surface of the base plate and being disposed between the electronic power assembly and the heat sink; an injectable conductive component disposed in a cavity defined by the electronic power assembly, the base plate, and the perimeter wall; and an encapsulant disposed around the electronic power assembly, at least a portion of the heat sink, and the perimeter wall to form a power module.

In some aspects, the techniques described herein relate to an apparatus, wherein the perimeter wall is monolithically formed within the heat sink.

In some aspects, the techniques described herein relate to an apparatus, wherein the perimeter wall is an adhesive film including at least one of silicone, an epoxy, or an acrylic material.

In some aspects, the techniques described herein relate to an apparatus, wherein the perimeter wall is an elastic seal.

In some aspects, the techniques described herein relate to an apparatus, wherein the heat sink is made of copper.

In some aspects, the techniques described herein relate to an apparatus, wherein the electronic power assembly includes an electronic component and a single-sided direct bond copper (DBC) structure.

In some aspects, the techniques described herein relate to an apparatus, wherein the electronic power assembly includes an electronic component, a dual-sided DBC structure, and a spacer.

In some aspects, the techniques described herein relate to an apparatus, wherein the injectable conductive component is in a liquid phase at an operating temperature of the electronic power assembly.

In some aspects, the techniques described herein relate to an apparatus, wherein the encapsulant is an epoxy molding compound (EMC).

In some aspects, the techniques described herein relate to an apparatus, further including a cover plate over the electronic power assembly, wherein the cover plate is secured to the base plate.

In some aspects, the techniques described herein relate to an apparatus, further including a clip assembly over the electronic power assembly, wherein the clip assembly is secured to the base plate.

In some aspects, the techniques described herein relate to an apparatus, including: a heat sink having a base plate and a plurality of fin structures; a first power sub-module coupled to a top surface of the base plate; a second power sub-module coupled to the top surface of the base plate; a first perimeter wall between the first power sub-module and a first of the plurality of fin structures, the first perimeter wall extending from a top surface of the base plate; a second perimeter wall between the second power sub-module and a second of the plurality of fin structures, the second perimeter wall extending from the top surface of the base plate; and an injectable conductive component disposed between the first power sub-module and the base plate, the injectable conductive component being surrounded by the first perimeter wall.

In some aspects, the techniques described herein relate to an apparatus, further including a cover plate coupled to the first power sub-module and the second power sub-module, the cover plate secured by a plurality of base plate fasteners.

In some aspects, the techniques described herein relate to an apparatus, wherein the first perimeter wall and the second perimeter wall are elastic seals.

In some aspects, the techniques described herein relate to an apparatus, further including an encapsulant formed around the cover plate, the first power sub-module and the second power sub-module, the base plate, and at least portions of the plurality of fin structures.

In some aspects, the techniques described herein relate to a method, including: forming a cavity, a first hole, and a second hole in a heat sink; coupling an electronic power assembly to the heat sink using an adhesive; injecting a conductive component into the cavity through the first hole; and sealing the first hole and the second hole.

In some aspects, the techniques described herein relate to a method, wherein sealing the first hole and the second hole includes installing fasteners.

In some aspects, the techniques described herein relate to a method, wherein sealing the first hole and the second hole includes clamping the heat sink to the electronic power assembly using a clip.

In some aspects, the techniques described herein relate to a method, wherein the second hole is an air vent, and the method further including attaching a filter to the air vent while injecting the conductive component.

In some aspects, the techniques described herein relate to a method, further including forming an encapsulant around the electronic power assembly and the heat sink.

### BRIEF DESCRIPTION OF THE DRAWINGS

FIGS. 1-4 are cross-sectional views of an injectable conductive component disposed in various power modules, according to implementations of the present disclosure.

FIGS. 5A and 5B are cross-sectional views of power modules equipped with clamps, according to implementations of the present disclosure.

FIG. 6 is a cross-sectional view of a power module that includes multiple power assemblies and heat sinks, according to an implementations of the present disclosure.

FIG. 7 is a flow diagram illustrating a method of fabricating a power module that has an injectable conductive component disposed therein, according to an implementations of the present disclosure.

FIGS. 8-12 illustrate steps in the method shown in FIG. 7, according to an implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

It is important to dissipate heat generated within power semiconductor devices to limit possible adverse effects of overheating such as dimensional variations, variable operating characteristics, and differential thermal expansion. Ineffective cooling of semiconductor devices may impose limitations on the design of power chip assemblies by constraining permissible power density, circuit density, or system speed. When heat is dissipated from a source (e.g., a power module) to a sink (e.g., a heat sink) by conduction, the heat transfer depends on the direct contact area between the source and the heat sink. Regardless of the smoothness of the abutting surfaces of the source and the sink and the amount of pressure that is applied to bring the surfaces together, there inevitably are irregularities that create air gaps between the adjoining surfaces. The presence of these air gaps at the interface tends to increase resistance to the flow of heat from the source to the sink. Thermal resistance of an interface between two surfaces can be reduced by providing an interface material that fills the air gaps and voids in the surfaces.

Various structures have been used to facilitate heat transfer between two surfaces. Examples used in electronic packaging include adhesives that attach O-rings or heat sinks to chips, greases and gels disposed between the surfaces, and deformable pads clamped between the surfaces. In each case, at least one of the objectives is to minimize the interfacial thermal contact resistance while maximizing the thermal conductivity of the transferring medium.

Current implementations of thermal interface materials (TIMs) used to couple a power assembly to a heat sink may have certain drawbacks. When a TIM is inserted between a source and a sink, there is a tradeoff between the thermal conductivity provided by the TIM and the contact resistance of the intervening material. For instance, common TIMs such as thermal greases or gels offer favorably low contact resistance due to their low viscosity, but they have limited thermal conductivity, typically less than, for example, 7 W/mK. Other types of TIMs such as solid films or sheets of metal foil, graphene, or graphite, have high thermal conductivity, up to about, for example, 30 W/mK. However, such materials tend to have low contact resistance due to their inconsistent surface morphology that may leave air gaps at the interfacial surfaces.

This disclosure relates to implementations of a direct cooling approach in which a power module can be bonded directly to a heat sink using a soldering or sintering process, without introducing an intervening layer. Use of such techniques to bond large surface areas carries a reliability risk due to potential weakness at the solder/sinter joint, which is addressed by the structures and methods described herein. In particular, the reliability of a direct bond can be improved by using an injectable conductive component (e.g., a liquid solder material) that remains in a liquid phase under operating conditions of the power module. The viscosity of the injectable conductive component (e.g., liquid solder) is less than, for example, 0.1 poise, compared to the viscosity of thermal grease, which is greater than 500 poise. This low viscosity allows the injectable conductive component to provide excellent wettability, forming continuous contact between adjoining surfaces, without being subject to degradation from thermal and mechanical stresses. Elemental constituents of the injectable conductive component can include gallium, indium, tin, zinc, each of which remains in a liquid phase at low temperatures, e.g., temperatures less than, for example, 30° C., and as low as, for example, 7.6° C. The temperature range of these liquids thus encompasses room temperature and most other operating conditions for power assemblies. Injectable conductive components (e.g., liquid solder alloys) of these metals offer high thermal conductivities between about 15 W/mK and about 30 W/mK.

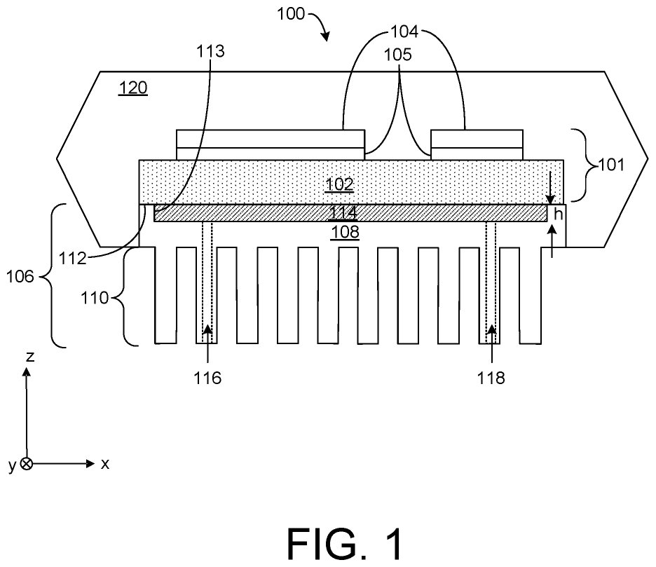

FIG. 1 is a cross-sectional view of a high-power semiconductor device module, or power module 100, in accordance with some implementations of the present disclosure. In some implementations, the power module 100 includes a high-power semiconductor chip assembly, or electronic power assembly 101. The electronic power assembly 101 includes a single-sided direct bond metal (DBM) structure 102 and at least one electronic component, e.g., semiconductor dies, or chips, 104 (two shown). The chips 104 are attached to, e.g., mounted on or coupled to, a top surface of the DBM structure 102 by a bonding agent 105, e.g., solder, or a silver (Ag) sintering material.

In some implementations, the chips 104 can include, for example, an iGBT (transistor) semiconductor die as shown on the left side, and an FRD (diode) semiconductor die as shown on the right side. However, other types of semiconductor dies can be used as one or more of the chips 104 in the electronic power assembly 101. In some implementations, the term “chips 104” can refer to a single semiconductor die. The chips 104 can fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In some implementations, the chips 104 can be fabricated on different substrates. For example, an iGBT chip 104 can be fabricated on a silicon substrate of semiconductor die 104a, while an FRD chip 104 can be fabricated on a silicon carbide substrate.

In some implementations, the DBM structure 102 can be a direct bond copper (DBC) type structure, a direct plating copper (DPC) type structure, or a direct bond aluminum (DBA) type structure. The DBM structure 102 may be referred to as a heat spreader. In some implementations, the DBM structure 102 has a thickness in a range of about 0.5 mm to about 3.0 mm.

The electronic power assembly 101 is coupled to a heat sink 106 that provides single-sided direct cooling of the electronic power assembly 101. In some implementations, the heat sink 106 includes a base plate 108 and a plurality of fins 110. The base plate conducts heat away from the electronic power assembly 101, to be dissipated by the fins 110. In the example shown, the fins 110 have a rectangular shape, however, the fins 110 are not so limited. Alternative shapes for the fins 110 include cylinders having circular, elliptical, triangular, or rhombus-shaped cross-sections, wavy structures, e.g., serpentine structures, and so forth. The fins 110 can be of uniform width, or some of the fins 110 can be wider than others. The fins 110 can be attached to, e.g., contiguous with, the base plate 108, or the fins 110 together with the base plate 108 can be portions of a unitary heat sink 106. The heat sink 106 can include one or more high-conductivity metals, e.g., copper (Cu).

In the implementation shown in FIG. 1, a cavity 113 can be formed monolithically in the base plate 108. Perimeter walls surrounding the cavity 113 form a pedestal 112, extending out from a surface of the base plate 108 of the heat sink 106. As seen from the top, the pedestal 112 forms a continuous wall around the perimeter of the cavity 113, whereas in the cross-sectional view shown in FIG. 1, the pedestal appears to be two separate structures. The cavity 113 can be defined, e.g., bounded, on top (e.g., on one side) by the DBM structure 102 and on the sides by the pedestal 112. Alternatively, the pedestal 112 can be attached around a perimeter of the base plate 108 to form a boundary of the cavity 113, instead of the cavity 113 being formed monolithically in the base plate 108. In the example shown, the cavity 113 has a rectangular shape, however, the shape of the cavity 113 is not so limited. Alternative shapes for the cavity 113 include circular, elliptical, polygonal, and so forth. In some implementations, the perimeter walls, e.g., the pedestal 112, can have a height h, above a top surface of the base plate 108, in a range of about 30 μm to about 200 μm. The electronic power assembly 101 can then be coupled to the heat sink 106 by loading edges of the DBM structure 102 onto the pedestal 112.

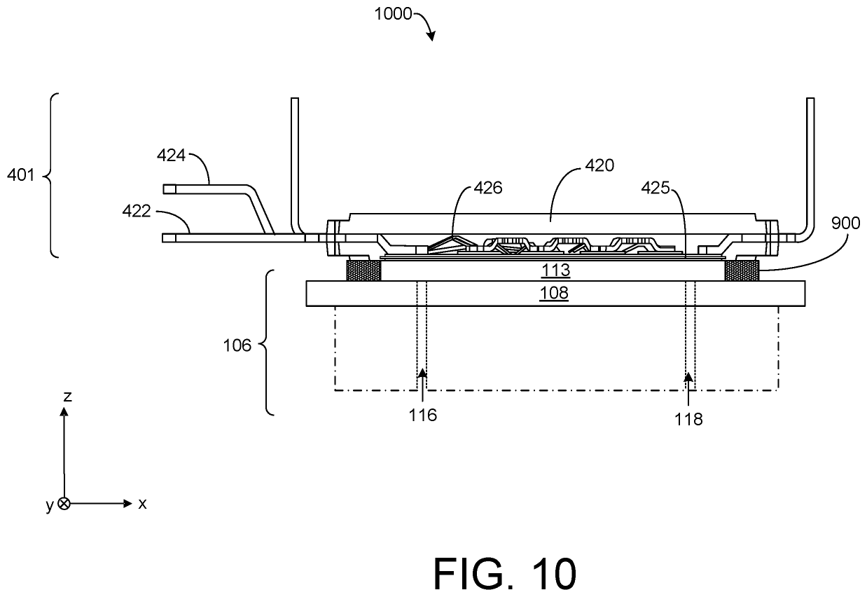

In some implementations, the cavity 113 is filled (e.g., at least partially filled, or entirely filled) with an injectable conductive component, e.g., a liquid solder 114. The cavity 113 is shown in FIGS. 1-6 after it has been filled. An empty cavity 113 is shown and described below with reference to FIG. 10. The liquid solder 114 can be introduced into the cavity 113 via a first opening, e.g., an injection hole 116, formed near a first end of the heat sink 106. The best heat conduction to the fins 110 may be achieved when the cavity 113 is entirely filled with the liquid solder 114, or another type of injectable conductive component. The injection hole 116 extends between a lower surface of the heat sink 106 and the cavity 113 formed therein. The injection hole 116 is open at both ends. In some implementations, the injection hole 116 is formed in one of the fins 110, so that the injection hole 116 extends through the fin 110 and through the base plate 108.

A second opening, e.g., a vent hole 118, can be formed in the heat sink 106 to allow displaced air to escape the cavity 113 as it is being filled with the liquid solder 114. In some implementations, the vent hole 118 is formed near a second end of the heat sink, opposite the first end, so that as the liquid solder 114 is injected into the cavity 113 through the injection hole 116, and thus displaces and compresses the air in the cavity 113. As more of the liquid solder 114 enters the cavity 113, the air is forced laterally across the cavity 113, toward the second end of the heat sink 106, and exits through the vent hole 118. The vent hole 118 extends between the cavity 113 and a lower surface of the heat sink 106. The vent hole 118 is open at both ends. In some implementations, the vent hole 118 is formed in one of the fins 110, so that the vent hole 118 extends through the entirety of the fin 110 and through the base plate 108 to the cavity 113. In some implementations, the vent hole 118 can be equipped with a micro-filter to prevent leakage of the liquid solder 114, while allowing trapped air to escape from the cavity 113. In some implementations, multiple vent holes 118 can be formed in the heat sink 106.

In accordance with implementations of the present disclosure, the injectable conductive component, e.g., the liquid solder 114, has the properties of low viscosity and high thermal conductivity as described above, which serve to accelerate heat transfer from the electronic power assembly 101 to the heat sink 106. The liquid solder 114, thus contained, remains in a liquid phase under operating conditions, e.g., an operating temperature, of the electronic power assembly 101.

The chips 104, the DBM structure 102, and at least a portion of the heat sink 106 can be encapsulated by a molding compound 120 to complete formation of the power module 100. In some implementations, the molding compound 120, e.g., a polymer material, can be an epoxy molding compound (EMC) that serves to seal and protect various components of the electronic power assembly 101 and the base plate 108. In some implementations, encapsulation with the molding compound 120 can occur prior to filling the cavity 113 with the liquid solder 114. Encapsulation can be accomplished by, for example, a process of injection molding or a process of transfer molding.

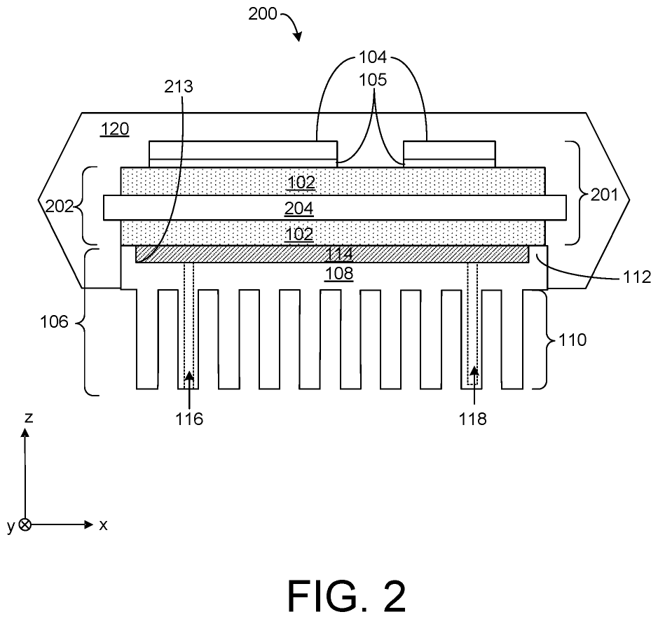

FIG. 2 is a cross-sectional view showing components of a power module 200, in accordance with some implementations of the present disclosure. The power module 200 includes a electronic power assembly 201 attached to the heat sink 106, which provides single-sided direct cooling of the electronic power assembly 201.

In some implementations, the electronic power assembly 201 is similar to the electronic power assembly 101, except that the electronic power assembly 201 is equipped with a dual DBM structure 202. In some implementations, the electronic power assembly 201 includes at least one electronic component, e.g., the chips 104, which are attached to, e.g., mounted on or coupled to, a top surface of a dual DBM structure 202 by a bonding agent 105, e.g., an epoxy, a solder, a silver (Ag) sintering material, and/or an adhesive.

In some implementations, the dual direct bond metal (DBM) structure 202 of the electronic power assembly 201 is designed as a three-layer structure that includes upper and lower DBM structures 102, separated by a dielectric 204. In some implementations, the dielectric 204 serves as a thermal mass disposed between two outer metal layers to draw in and absorb heat. The dielectric 204 also provides electrical insulation between the upper and lower DBM structures 102. In some implementations, the dielectric 204 can be made of a ceramic material, e.g., aluminum oxide (Al₂O₃).

Similar to the example shown in FIG. 1, the heat sink 106 in power module 200 has a cavity 113 formed monolithically therein, bounded on the sides by the pedestal 112. Once it is formed, the cavity 113 can be filled with an injectable conductive component, e.g., the liquid solder 114 as described above, by injection through the injection hole 116 in one of the fins 110. The vent hole 118, formed in another one of the fins 110, allows displaced air to escape the cavity 113 as it is being filled with the liquid solder 114. In some implementations, the vent hole 118 can be equipped with a micro-filter to prevent leakage of the liquid solder 114, while allowing trapped air to escape from the cavity 113. The liquid solder 114, thus contained, remains in a liquid phase under operating conditions, e.g., an operating temperature, of the electronic power assembly 201.

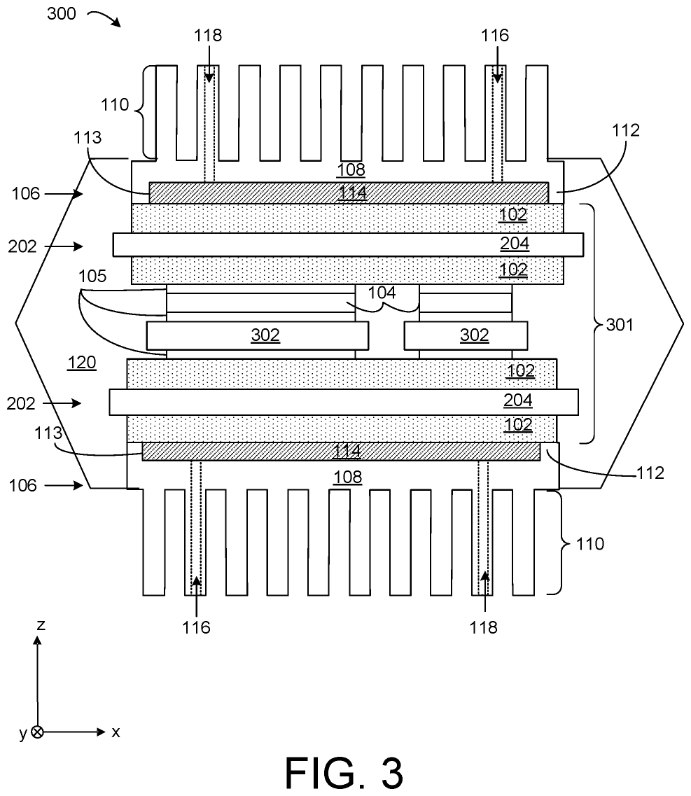

FIG. 3 is a cross-sectional view showing components of a power module 300, in accordance with some implementations of the present disclosure. The power module 300 is similar to the power module 200 except that the power module 300 includes an electronic power assembly 301 that is equipped with two dual DBM structures 202, and two heat sinks 106, which provide dual-sided cooling for at least one electronic component of the electronic power assembly 301, e.g., the chips 104.

In some implementations, the electronic power assembly 301 further includes spacers 302 inserted between each chip 104 and one of the dual DBM structures 202 to rapidly dissipate heat generated therein. In some implementations, the spacers 302 can be bonded to the chips 104 and to the upper DBM structure 102 by the bonding agent 105. The spacers 302 are designed to absorb heat generated by the chips 104 and transmit the heat to the adjacent DBM structure 202. The spacers 302 can include materials having a high thermal conductivity such as, for example, copper or alloys thereof. One such copper alloy that can be used as the spacer 302 is a copper-molybdenum (CuMo) alloy. The choice of whether to use pure copper or, for example, CuMo, may be made based on heat dissipation requirements for the type of chip(s) 104 that are coupled to the spacer 302. For example, an FRD chip may operate at a higher voltage or current than an IGBT chip, and therefore may generate more heat and may need more efficient heat dissipation as provided by a spacer 302 that is made of pure copper. Cost may also be a factor. Pure copper can be less expensive than a copper alloy like CuMo, while providing faster heat dissipation. In some implementations, spacers 302 have a thickness in a range of about 0.2 mm to about 3.0 mm.

As in the examples shown in FIGS. 1 and 2, each of the heat sinks 106 in the power module 300 shown in FIG. 3 also has a cavity 113 formed monolithically therein, bounded on the sides by the pedestals 112. Once they are formed, each of the cavities 113 can be filled with an injectable conductive component, e.g., the liquid solder 114 as described above, by introduction through an injection hole 116 in one of the fins 110 of the respective heat sink 106. The vent hole 118, formed in another one of the fins 110, allows displaced air to escape the cavity 113 as it is being filled with the liquid solder 114. In some implementations, the vent hole 118 can be equipped with a micro-filter to prevent leakage of the liquid solder 114, while allowing trapped air to escape from the cavity 113. The liquid solder 114, thus contained, remains in a liquid phase under operating conditions, e.g., an operating temperature, of the electronic power assembly 301.

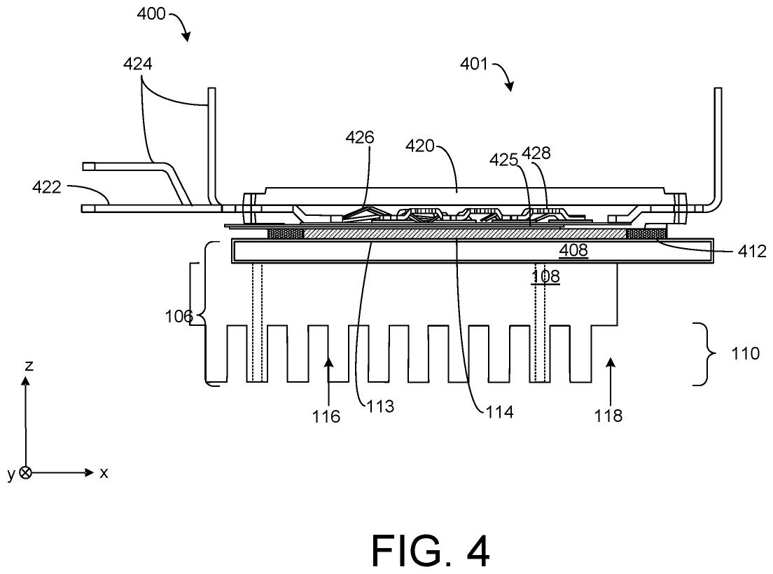

FIG. 4 is a cross-sectional view showing components of a power module 400, in accordance with some implementations of the present disclosure. The power module 400 includes an encapsulated electronic power assembly 401 attached to the heat sink 106 by a sealing material 412. The encapsulated electronic power assembly 401 includes a DBM structure 102 and at least one electronic component, e.g., chips 104. The sealing material 412 can be, for example, an elastic seal such as an O-ring or a gasket, or an adhesive film that includes e.g., a silicone, an epoxy, or an acrylic material, or a combination thereof. If an adhesive is used as the sealing material 412, the adhesive can have a thickness in a range of about 100 μm to about 200 μm. In addition to the power assembly being pre-encapsulated, the overall power module 400, including a portion of the heat sink 106, can further be encapsulated using a molding compound.

In the power module 400, the heat sink 106 is modified to include a base plate cap 408 over the base plate 108. In some implementations, the base plate cap 408 extends laterally beyond edges of the base plate 108. Instead of forming a cavity 113 monolithically in the base plate cap 408, the power module 400 supports a cavity 113 between the encapsulated electronic power assembly 401 and the base plate cap 408. That is, the sealing material 412 forms perimeter walls around sides of a cavity bounded by the base plate cap 408 on the bottom, and the encapsulated electronic power assembly 401 on the top. Once it is formed, the cavity 113 can be filled with an injectable conductive component, e.g., the liquid solder 114 as described above, by injection through the injection hole 116 in one of the fins 110 of the heat sink 106. The vent hole 118, formed in another one of the fins 110, allows displaced air to escape the cavity 113 as it is being filled with the liquid solder 114. In some implementations, the vent hole 118 can be equipped with a micro-filter to prevent leakage of the liquid solder 114, while allowing trapped air to escape from the cavity 113. The injection hole 116 and the vent hole 118 extend through the entirety of the fins 110, through the base plate 108, and through the base plate cap 408 to the cavity 113. The liquid solder 114, thus contained, remains in a liquid phase under operating conditions, e.g., an operating temperature, of the encapsulated electronic power assembly 401.

FIG. 4 further illustrates electrical connections, e.g., copper connectors to the encapsulated electronic power assembly 401, including a lead frame 422, leads 424, a die attach pad (DAP) 425, wire bonds 426, and clips 428. The chips 104 of the power assembly 401 can be attached to, e.g., mounted to, the die attach pad 425. In some implementations, an upper DBM structure 102 can serve as the die attach pad 425. The leads 424 provide signal paths from the encapsulated electronic power assembly 401 to external devices, power supplies, and ground connections. The wire bonds 426 and clips 428 within the encapsulated electronic power assembly 401 can be used to couple the lead frame 422 to semiconductor devices on the chips 104.

The power module 400 is shown in FIG. 4 prior to final packaging, and therefore the molding compound 120 is not present. However, the encapsulated electronic power assembly 401 is surrounded by an encapsulant 420, e.g., an epoxy molding compound, prior to attachment to the heat sink 106. The molding compound 120 (not shown in FIG. 4) can be formed around the encapsulated electronic power assembly 401, portions of the leads 424, and portions of the heat sink 106 either prior to, or after, injecting the liquid solder 114.

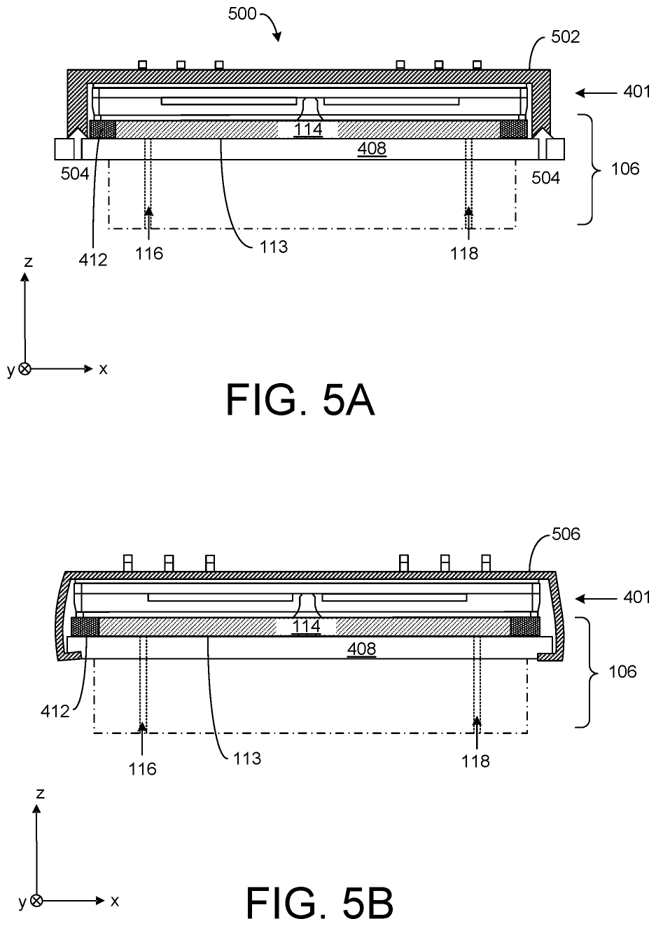

FIGS. 5A and 5B illustrate two implementations of a power module 500, in accordance with the present disclosure. The power module 500 is similar to the power module 400 in that the liquid solder 114 is disposed between the encapsulated electronic power assembly 401 on top, the heat sink 106 on the bottom, and a sealing material 412 that forms perimeter walls on the sides. However, the power module 500 additionally secures the encapsulated electronic power assembly 401 to the heat sink 106 using a clamp. In FIG. 5A, the clamp is in the form of a cover plate 502 secured to the base plate cap 408 by base plate fasteners, e.g., screws 504. In some implementations, the screws 504 are driven through the base plate cap 408. In FIG. 5B, the clamp is in the form of a clip assembly 506 that is secured to the base plate cap 408. In some implementations, the clip assembly 506 wraps around the base plate cap 408 and thus applies tension to hold the encapsulated electronic power assembly 401 against the sealing material 412.

Once the clamp is positioned and secured, the cavity 113 can be filled with the liquid solder 114 as described above, by injection through the injection hole 116 in one of the fins 110. The vent hole 118, formed in another one of the fins 110, allows displaced air to escape the cavity 113 as it is being filled with the liquid solder 114. In some implementations, the vent hole 118 can be equipped with a micro-filter to prevent leakage of the liquid solder 114, while allowing trapped air to escape from the cavity 113. An encapsulant, e.g., the molding compound 120 (not shown in FIGS. 5A, 5B), can be formed around the clamp and portions of the heat sink 106 either prior to, or after, injecting the liquid solder 114.

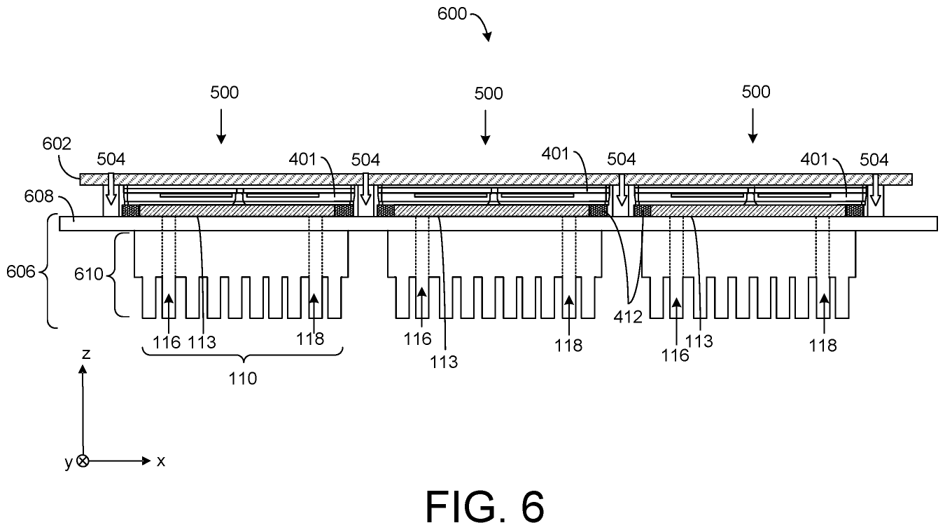

FIG. 6 is a cross-sectional view showing components of a power module 600, in accordance with some implementations of the present disclosure. The power module 600 provides a compact arrangement combining multiple power sub-modules, e.g., multiple power modules 500 each including an encapsulated electronic power assembly 401. In some implementations of the power module 600, multiple encapsulated power assemblies 401 are attached to a single heat sink 606 by sealing materials 412 with the aid of a common cover plate 602. In the power module 600, the heat sink 606 includes a common base plate cap 608 and plurality of fin structures 610, each fin structure 610 having a base plate 108 and fins 110. In some implementations, base plate fasteners, e.g., the screws 504, couple the common cover plate 602 to a top surface of the common base plate cap 608, between each of the power sub-modules. Pressure exerted by the screws 504 serves to hold each of the encapsulated electronic power assemblies 401 against the sealing material 412. In each one of the multiple power sub-modules within power module 600, an injectable conductive component, e.g., the liquid solder 114, is disposed between an encapsulated electronic power assembly 401, perimeter walls formed by the sealing material 412, e.g., elastic seals, and a top surface of the common base plate cap 608. The use of the common cover plate 602 and the common base plate 608 in the power module 600 saves space and provides additional mechanical stability.

As described above, the liquid solder 114 can be introduced into each of the cavities 113 through the injection holes 116, which extend through the entirety of the fins 110, through the base plate 108, and through the base plate cap 608.

An encapsulant, e.g., an epoxy molding compound, can be formed around the common cover plate 602, the multiple power sub-modules, the common base plate, and at least portions of the multiple fin structures, to complete the power module 600.

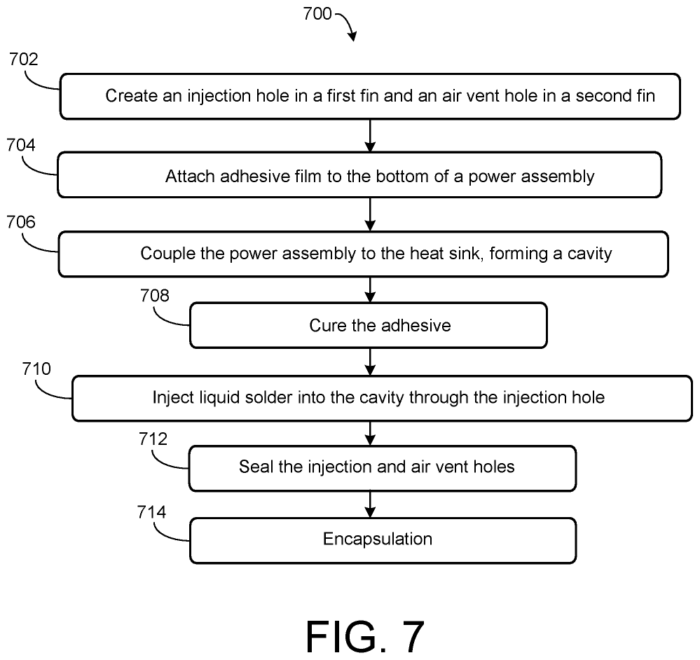

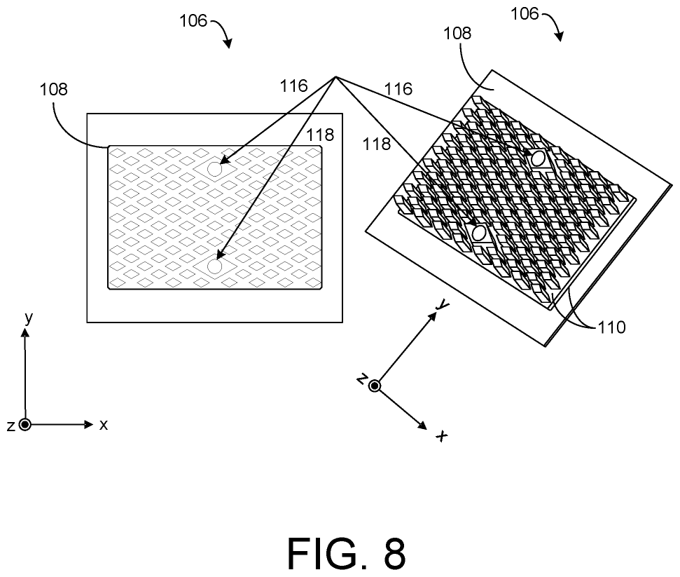

FIG. 7 is a flow chart illustrating a method 700 for fabricating a power module, e.g., the power module 400, in accordance with some implementations of the present disclosure. Operations 702-210 of the method 700 can be carried out to form the power module 400, according to some implementations as described below with respect to FIGS. 8-12. Operations of the method 700 can be performed in a different order, or not performed, depending on specific applications. It is noted that the method 700 may not produce a complete power module 400. Accordingly, it is understood that additional processes can be provided before, during, or after method 700, and that some of these additional processes may be briefly described herein.

At 702, the method 700 includes forming the injection hole 116 and the vent hole 118 in respective fins 110 of the heat sink 106, in accordance with an implementation of the present disclosure as shown in FIG. 8. FIG. 8 shows a top plan view of the heat sink 106 on the left side, and a bottom plan view of the heat sink 106 on the right side, rotated by 45 degrees. The fins 110, arranged in a two-dimensional array, e.g., a matrix, protrude from the bottom side of the heat sink 106. In some implementations, the heat sink 106 can be, for example, a heavy metal plate, e.g., a copper plate, and the fins 110 are bulky metal extensions capable of dissipating heat efficiently. The holes 116 and 118 can be created in the heat sink 106 by precision drilling, for example. In some implementations, the holes 116 and 118 can be drilled into selected fins. Alternatively, the holes 116 and 118 can replace selected fins.

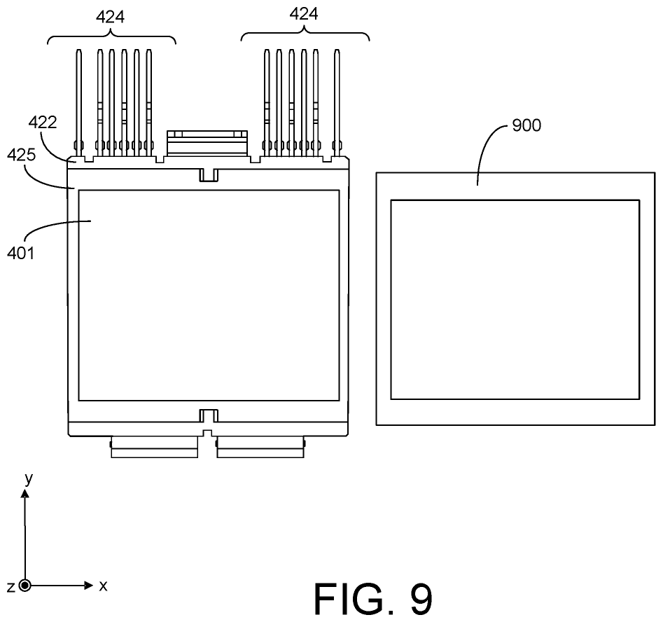

At 704, the method 700 includes attaching sealing material, e.g., an adhesive film 900, to an underside of the encapsulated electronic power assembly 401, in accordance with an implementation of the present disclosure as shown in FIG. 9. The bottom surface of the encapsulated electronic power assembly 401 is formed by the encapsulant 420. A central area of the encapsulated electronic power assembly 401 includes the die attach pad (DAP) 425 to which the chips 104 are mounted. FIG. 9 illustrates the lead frame 422 having leads 424 that extend outward, away from the DAP.

At 706, the method 700 includes coupling the encapsulated electronic power assembly 401 to the heat sink 106, in accordance with an implementation of the present disclosure as shown in FIG. 10. FIG. 10 illustrates a power module 1000 in which a cavity 1002 is formed when the encapsulated electronic power assembly 401 and the heat sink 106 are joined. The cavity 1002 is bounded by the encapsulant 420 on the top, the base plate 108 of the heat sink 106 on the bottom, and the adhesive film 900 on the sides.

At 708, the method 700 includes curing the adhesive film 900 to couple the power assembly 401 to the base plate 108 of the heat sink 106, in accordance with an implementation of the present disclosure as shown in FIG. 10. The curing operation can include, for example, applying heat to the adhesive film at a temperature in a range of about 20 C to a maximum of about 200 C to prevent internal solder re-melt.

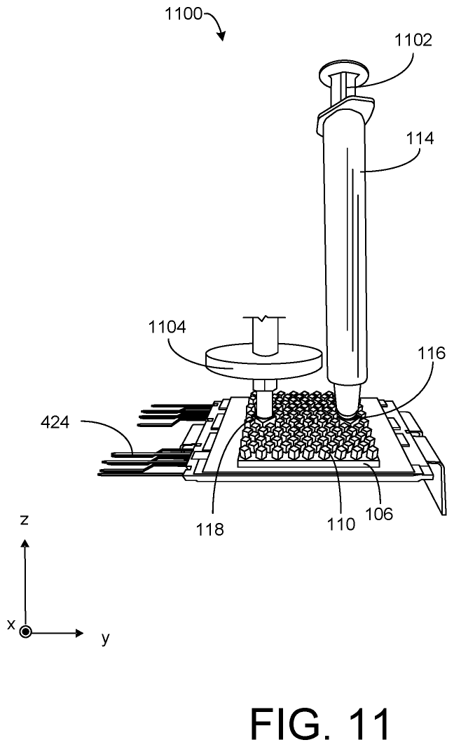

At 710, the method 700 includes introducing the liquid solder 114 into the cavity 1002 through the injection hole 116, in accordance with an implementation of the present disclosure as shown in FIG. 11. FIG. 11 illustrates an injection apparatus 1100, in which the heat sink 106 is inverted to expose the fins 110, the injection hole 116, and the vent hole 118. An injection device, e.g., a syringe 1102, containing the liquid solder 114 is inserted into the injection hole 116. Operation of the syringe 1102 pressurizes the liquid solder 114 and forces it through the heat sink 106 into the cavity 113. Meanwhile, a micro-filter 1104 can be attached to the vent hole 118. In some implementations, the micro-filter 1104 can be in the form of a porous cap that can trap particles greater than 0.2 μm in the air that is displaced from the cavity 1002, as the cavity 1002 is filled with the liquid solder 114.

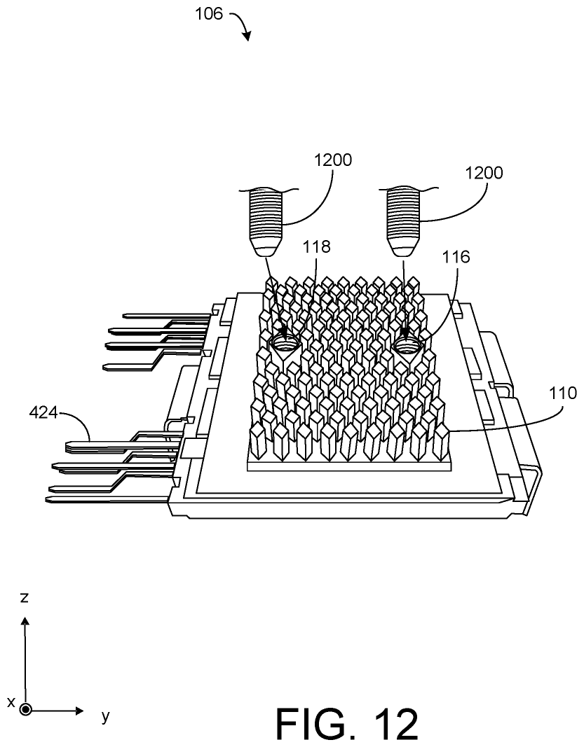

At 712, the method 700 includes sealing the holes in the heat sink 106, in accordance with an implementation of the present disclosure as shown in FIG. 12. FIG. 12 illustrates the heat sink 106 after injection of the liquid solder 114 is complete. In FIG. 12, the injection apparatus 1100 has been removed. That is, the syringe 1102 has been removed from the injection hole 116 and the micro-filter 1104 has been removed from the vent hole 118. Both the injection hole 116 and the vent hole 118 can then be sealed by installing plugs e.g., set screws 1200, to prevent the liquid solder 114 from leaking out of the cavity 113. FIG. 12 further illustrates that the particular fins 110 through which the injection hole 116 and the vent hole 118 extend can be larger, e.g., wider, than other fins 110 in the heat sink 106.

At 714, the method 700 includes an encapsulation operation, in accordance with an implementation of the present disclosure. In some implementations, the encapsulation operation surrounds the encapsulated electronic power assembly 401, the adhesive film 900, and at least portions of the heat sink 106 with an encapsulant, e.g., an epoxy molding compound, to complete fabrication of the power module 400.

As described above, various implementations of a power module can couple an electronic power assembly 101 to a heat sink 106 directly with liquid solder 114, to avoid addition of a thermal interface material. Because the liquid solder 114 remains in the liquid phase during operation of the power module, containment of the liquid solder 114 can be accomplished by forming a cavity 113 between opposing surfaces and a perimeter wall, and then injecting the liquid solder 114 into the cavity 113 through holes in the heat sink 106. Use of the liquid solder 114 avoids interfacial coupling problems encountered with current structures.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
an electronic power assembly;
a heat sink having a base plate and a plurality of fins;
a perimeter wall extending from a surface of the base plate and being disposed between the electronic power assembly and the heat sink;
an injectable conductive component disposed in a cavity defined by the electronic power assembly, the base plate, and the perimeter wall; and
an encapsulant disposed around the electronic power assembly, at least a portion of the heat sink, and the perimeter wall to form a power module.

2. The apparatus of claim 1, wherein the perimeter wall is monolithically formed within the heat sink.

3. The apparatus of claim 1, wherein the perimeter wall is an adhesive film including at least one of silicone, an epoxy, or an acrylic material.

4. The apparatus of claim 1, wherein the perimeter wall is an elastic seal.

5. The apparatus of claim 1, wherein the heat sink is made of copper.

6. The apparatus of claim 1, wherein the electronic power assembly includes an electronic component and a single-sided direct bond copper (DBC) structure.

7. The apparatus of claim 1, wherein the electronic power assembly includes an electronic component, a dual-sided DBC structure, and a spacer.

8. The apparatus of claim 1, wherein the injectable conductive component is in a liquid phase at an operating temperature of the electronic power assembly.

9. The apparatus of claim 1, wherein the encapsulant is an epoxy molding compound (EMC).

10. The apparatus of claim 1, further comprising a cover plate over the electronic power assembly, wherein the cover plate is secured to a cap on the base plate.

11. The apparatus of claim 1, further comprising a clip assembly over the electronic power assembly, wherein the clip assembly is secured to a cap on the base plate.

12. The apparatus of claim 1, wherein the heat sink includes an opening having a plug disposed therein.

13. The apparatus of claim 12, wherein the opening extends through a fin and through the base plate.

14. An apparatus, comprising:
a heat sink having a base plate and a plurality of fin structures;
a first power sub-module coupled to a top surface of the base plate;
a second power sub-module coupled to the top surface of the base plate;
a first perimeter wall between the first power sub-module and a first of the plurality of fin structures, the first perimeter wall extending from a top surface of the base plate;
a second perimeter wall between the second power sub-module and a second of the plurality of fin structures, the second perimeter wall extending from the top surface of the base plate; and
an injectable conductive component disposed between the first power sub-module and the base plate, the injectable conductive component being surrounded by the first perimeter wall.

15. The apparatus of claim 14, wherein the first perimeter wall and the second perimeter wall are elastic seals.

16. The apparatus of claim 14, further comprising a cover plate coupled to the first power sub-module and the second power sub-module, the cover plate secured by a plurality of base plate fasteners.

17. The apparatus of claim 16 further comprising an encapsulant formed around the cover plate, the first power sub-module and the second power sub-module, the base plate, and at least portions of the plurality of fin structures.

18. A method, comprising:
forming a cavity, a first hole, and a second hole in a heat sink;
coupling an electronic power assembly to the heat sink using an adhesive;
injecting a conductive component into the cavity through the first hole; and
sealing the first hole and the second hole.

19. The method of claim 18, wherein sealing the first hole and the second hole includes installing a first plug in the first hole and a second plug in the second hole.

20. The method of claim 18, wherein sealing the first hole and the second hole includes clamping the heat sink to the electronic power assembly using a clip.

21. The method of claim 18, wherein the second hole is a vent, and the method further comprising attaching a filter to the vent while injecting the conductive component.

22. The method of claim 18, further comprising forming an encapsulant around the electronic power assembly and the heat sink.
